(19) United States
(12) Patent Application Publication
(10) Pub. No.: US 2011/0000524 A1
(43) Pub. Date: Jan. 6, 2011

(54) SOLAR MODULE

(76) Inventors: Michael Busch, Halle (DE); Jorg Bagdahn, Kothen (DE)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/919,695

(22) PCT Filed: Mar. 3, 2009
(86) PCT No.: PCT/DE2009/000305

§ 371 Date: Aug. 26, 2010

(30) Foreign Application Priority Data
Mar. 3, 2008 (DE) 10 2008 012 286.6
May 14, 2008 (DE) 20 2008 006 549.6

(51) Int. Cl. H01L 31/055

(52) U.S. Cl. 136/247

(57) ABSTRACT

A solar module is described having a flatly implemented solar cell configuration, on whose rear side a rear side construction is provided and on whose front side a radiation-transparent front pane is provided, having a solidifying grouting compound, which encloses the solar cell configuration between rear side construction and front pane and transmits mechanical loads, and which connects the surface of the front pane facing toward the rear side construction over its entire area to the rear side construction and completely encloses the solar cell configuration. The rear side construction is implemented as a separate module, which is a plastic carrier produced using injection molding, injection-compression molding, or compression, or in the form of a stiff ceramic or organic planar element.

### BACKGROUND OF THE INVENTION

1. Field of the Invention

The invention relates to a solar module having a flatly implemented solar cell configuration, on whose rear side a rear side construction is provided and on whose front side a radiation-transparent front pane is provided, having a grouting compound, which encloses the solar cell configuration between the rear side construction and front pane, is capable of solidifying, and transmits mechanical loads, and which connects the surface of the front pane facing toward the rear side construction over its entire area to the rear side construction and completely encloses the solar cell configuration.

2. Description of the Prior Art

Solar modules are photovoltaic components for direct generation of electrical current from sunlight. Key factors for cost-effective generation of solar current are the production costs and the durability of the solar modules.

Solar modules typically comprise a composite made of a front pane, the interconnected solar cells, which are enclosed by an embedding material, and a rear side construction. A widespread variant of solar modules is also provided with aluminum profiles for the handling and later retaining, which are attached peripherally as a frame and sometimes also as struts for support. The individual elements of a solar module have the following functions to fulfill:

The front pane, typically made of glass, approximately 3-4 mm thick, is used for protection from mechanical and weathering influences and provides a part of the mechanical stability of the module. It must be highly transparent, preferably made of colorless glass having 90-92% transmission degree in the upper spectral range, in order to keep absorption losses in the optical spectral range from approximately 300 nm to 1500 nm as low as possible and thus keep the efficiency of the typically used silicon solar cells as high as possible.

The embedding material, namely, ethylene vinyl acetate films or EVA films frequently employed for this purpose, are used for embedding the interconnected cells and gluing the entire module composite. Embedding of this type is not capable of transmitting mechanical strain which is an aspect that is discussed in greater detail hereafter.

A composite film, typically comprising polyvinyl chloride (PVF) and polyethylene terephthalate (PET) or PVF and aluminum, is employed on the module rear side for protecting the solar cells and the embedding material from moisture and oxygen. In some cases, a glass pane is also used on the rear side, as on the front side.

Vacuum lamination represents a widespread technology for embedding, because the formation of air bubbles is extensively prevented by the vacuum during lamination. EVA melts during the lamination at approximately 150° C., flows around the interconnected solar cells, and is thermally cross-linked.

The encapsulation or embedding materials used must have good barrier properties against water vapor and oxygen, in particular because corrosion-related damage arises on metal contacts due to water vapor or oxygen and degradation of the EVA material occurs. The front and rear sides of the solar module thus must have high weathering stability and protect the embedded solar cells from corrosion by barrier action for example against water vapor and oxygen.

Fundamentally, solar modules must have high mechanical stability, in particular high bending stiffness and bending strength, for use, for example, on house roofs, in order to be able to withstand the possible loads in operation, such as wind and snow loads, without damage. The mechanical stability of known solar modules can be ensured by its rear side, its front side, and/or by further additional supports, for example, in the form of aluminum frames, aluminum struts, or a stable support construction, which prevents sagging of the module under load.

In addition, solar modules must achieve very long operating times, in order to ensure their profitability. Current typical requirements for the lifetime of the solar modules are at least 25 years, with a rising tendency. In operation, the solar modules are subject to high mechanical strains, for example, by wind and snow loads, and by cyclically occurring temperature variations, which may be from 80° C. in the case of full sunlight, down to below the freezing point.

High material and manufacturing costs, caused by: special front glass, special composite films for the rear side, vacuum lamination, aluminum frame, the required mechanical work, such as soldering of the electrical lines, installation and contacting of the sockets, and the relatively long processing times for the lamination and cross-linking of the EVA, result in a comparatively high proportion of the costs for the modular construction of the total costs which are in the double-digit percentage range.

In addition, conventional solar modules have a high weight due to the relatively thick front glass pane, which in turn requires stable and costly retaining structures.

A further important point is the heat dissipation. In full sunlight, the modules heat up to 80° C., which results in a reduction of the efficiency of the solar cells.

Various proposals do exist for reducing the production costs of the solar modules through more cost-effective components and production methods. However, these proposals are also not properly rewarding. The patent EP000000325369A2 (abbreviation EP) and the published application DE 10101 770 A1 of Bayer AG (abbreviation DE) are significant for the invention, in addition to possible further publications.

A photovoltaic module is described in EP 325369 A2, which is based on embedding a “photovoltaic panel” in a reactive elastomer. The photovoltaic panel comprises a combination of a layer made of transparent material, a configuration of interconnected photovoltaic cells, and a rear side layer, which does not offer any mechanical stability.

A solar module is described in DE 10 101 770 A1, in which the solar cells are completely extrusion coated by a polyurethane material, either by one single or by two different polyurethane materials. The transparent polyurethane is soft like an elastomer, so that its bending stiffness is negligible. This results in only slight bending stiffness of the entire solar module. A further described variant of a solar module is that in which the solar cells are fixed on a molded part which is used as the module rear side, on which a transparent polyurethane is then sprayed. In this variant, a higher bending stiffness of the solar module can be achieved by using a stiff molded part as the module rear side, such as a polycarbonate reinforced using glass fibers. Fundamentally, solar modules are desired which have high mechanical stability. A highly stable module, typically having an area of approximately 1.40 m², is one which, without further additional supports, such as aluminum frames, aluminum struts, a stable support construction, which prevents sagging of the module under load by only supporting itself and withstands all mechanical load tests prescribed in the relevant standards.

In order to achieve these requirements defined for a solar module having higher mechanical stability, either the rear side of the solar module must be implemented as relatively thick, which is accompanied by a poorer heat dissipation and a higher weight of the solar module, or the glass plate must be implemented as being relatively thick. Both cases result in a high weight of the module.

Furthermore, a solar module can be inferred from DE 102 30 392 A1, which provides a solar cell configuration between upper and lower plates comprising acrylic glass, which is enclosed by a filling compound, which additionally connects the upper plate to the lower plate. This configuration results in high module weights for large-area, robust solar modules, which are provided for the purpose of solar powered energy sources having typical area sizes of at least one square meter and/or for roof installation on buildings.

In a similar way, a comparable solar module can be inferred from DE 198 34 016 A1, which provides a rear side construction comprising a cast or extruded PMMA material, and a cover plate comprising Plexiglas, between which a solar cell configuration is introduced and is filled using a radiation-transparent silicone gel. These solar modules may be implemented as stiff and simultaneously light due to the hollow chamber structure of the rear side construction, but the rear side construction must be implemented as very thick for this purpose, which is connected to significant heat buildup and has a negative effect on the efficiency. The heat dissipation is only possible in the case of these elements if the hollow chambers of the rear side construction are intentionally used for the heat dissipation, which however typically cannot be implemented in the case of modules provided for roof installation on buildings.

### SUMMARY OF THE INVENTION

The invention is solar modules having higher mechanical stability, in particular higher bending stiffness and bending strength, so that, for example, a module of this construction having an area of approximately 1.40 m², can without further additional supports, such as aluminum frames, aluminum struts, a stable support construction, which prevents sagging of the module under load, only supports itself while withstanding all mechanical load tests prescribed in the relevant standards, based on photoactive elements. The solar module is particularly cost-effective, robust in relation to external influences, has a long lifetime, and ensures high efficiency even in the case of high sunlight temperatures.

A solar module according to the invention has a flatly implemented solar configuration, on whose rear side a rear side construction is provided and on whose front side a radiation-transparent front pane is provided, having a grouting compound, which encloses the solar cell configuration between rear side construction and front pane, is capable of solidifying, and transmits mechanical loads, and connects the surface of the front pane facing toward the rear side construction over its entire area to the rear side construction and completely encloses the solar cell configuration. The invention is distinguished in that the rear side construction is implemented as a separate module, in the form of a plastic carrier which is produced using injection molding, injection-compression molding, or compression, and the plastic carrier provides a metal electrical terminal structure, which is integrated in the plastic carrier, for an electrical connection to the solar cell configuration in such a manner that at least one section of the terminal structure is completely enclosed by the plastic carrier material and at least one other section of the terminal structure has a free contact area facing toward the solar cell configuration.

In an alternative embodiment according to the invention, the rear side construction is implemented as a separate module which comprises a stiff ceramic or organic planar element, in which a metal electrical terminal structure for an electrical connection to the solar cell configuration is also integrated. At least one section of the electrical terminal structure is completely enclosed by the material of the rear side construction and at least one other section of the electrical terminal structure has a free contact area facing toward the solar cell configuration. In a preferred embodiment variant of a solar module, at least one free contact area is used for producing an electrical contact to the solar cell configuration. A further free contact area is used for the electrical connection of the solar module to an external consumer circuit, via which the solar power can be tapped.

The hybrid materials advantageously form a material composite. The structure of the rear side construction contributes to improved mechanical surface stiffness, so that in particular large-area solar modules of one square meter size or more are subject to surface deformations to a much lesser extent than conventional solar modules. The introduction and implementation of the electrical terminal structure within the rear side construction are performed with both the electrical connection of the solar cell configuration between the rear side construction and the cover plate, and also for the purpose of a structural surface stiffening, comparable to a reinforcement. For example, implementing at least sections of the electrical terminal structure, which are completely enclosed by the material of the rear side construction, as strip-shaped, lattice, or in the form of extruded profiles, provides the electrical terminal structure with improved bending stiffness.

In addition to providing a metal terminal structure, taking further precautions which increase the surface stiffness of the rear side construction provides additional support structures at the rear side construction, which do not necessarily comprise an electrically conductive material, such as metal, but rather one or more of the following materials: glass, ceramic, plastic, or fiber-reinforced composite material. An additional support structure of this type is manufactured like the electrical terminal structure from a different material than the material of the rear side construction and in turn contributes to a hybrid structure of the rear side construction.

In a particularly preferred embodiment, the solar module thus comprises a light, mechanically stable plastic carrier, which is produced using injection molding, injection-compression molding, or compression, having at least the above-explained electrical terminal structure on the rear side, a transparent front pane, for example, made of glass, glass-ceramic, or a transparent plastic, for example, based on PMMA, on the front side, the interconnected and contacted solar cells being located in the intermediate space between front pane and plastic carrier, and an adhesive layer, which glues the plastic carrier and the front pane together and fills up the intermediate space between plastic carrier and front pane without bubbles, and which also encapsulates the solar cells and the contact system.

If a solar module mechanically is considered to be a plate, the bending stiffness increases with the third power of the plate thickness. The thickness of the solar module is increased by the thickness of the plastic carrier, the thickness of the front pane, and the thickness of the adhesive layer between front pane and plastic carrier. The hybrid-structure plastic carrier provides a significant part of the mechanical stability of the solar module. The front pane comprises a material having a significant bending stiffness. Thus, for example, PMMA has a bending stiffness which is higher by approximately a factor of 10 than transparent polyurethane of equal thickness and approximately equal density. Through the gluing of the front pane and plastic carrier over the entire area by the adhesive layer, the stiff front pane also contributes to the mechanical stability of the solar module. This has the result that the plastic carrier, at least having the electrical terminal structure integrated therein, can also be implemented as significantly thinner on the rear side than if the front side (as in the case of polyurethane) no longer contributes to the stability, which in turn results in significant advantages in the heat dissipation and in the weight [-] with the density of polyurethane and PMMA being approximately equal.

A further advantage of the direct gluing of front pane and plastic carrier is that through the gluing, the adhesive layer between front pane and plastic carrier, which contains the solar cells, shifts closer to the neutral bending line or neutral chamfer, which results in lower mechanical tensions in the adhesive layer and thus also in the solar cells and permits a significantly longer lifetime to be expected as a result of the lower load level.

It is noted as a further advantage that due to the lower mechanical tensions in the neutral bending line, not only elastic glued joints, but also structural glued joints having less soft, non-elastomeric adhesives may be used, which in turn results in significantly higher bending stiffness and bending strength. In particular the electrical terminal structure has its free contact areas as distributed inside the rear side construction, in addition to electrical contacting, for exact spatial arrangement of the solar cell configuration relative to the rear side construction and above all positioning within the neutral chamfer of the solar module.

Due to the shaping of the plastic carrier by injection molding, injection-compression molding, or compression, its production is performed at the typical low cycle times for these technologies, in the range between a few minutes to less than one minute. Suitable materials for the plastic carrier are, for example, PBT, PET, PA, PMMA, PC, PP, or biopolymers such as PLA or PLA copolymers, preferably having reinforcement fibers, such as glass fibers or carbon fibers or other reinforcement fibers or fillers or mixtures of the above-mentioned for improving the mechanical properties which are in particular the stiffness and strength. The incorporation of the above-mentioned fibers is performed using compounding technologies either in a separate processing step prior to the shaping, or in-line in the same processing step as the shaping using the injection-molding compounding technology.

The plastic for the carrier can additionally be equipped with a filler which increases the thermal conductivity, such as metal fibers or powdered copper. Furthermore, it can be equipped with a filler for reducing the thermal expansion of the unfilled polymer, such as chalk, glass lamina, or silicates. The incorporation of the above-mentioned fillers is performed using known compounding technologies, either in a separate processing step prior to the shaping, or in-line in the same processing step as the shaping using the injection-molding compounding technology.

The plastic carriers are advantageously integrated in the process of the shaping using injection molding, injection-compression molding, or compression with the electrical terminal structure, that is, the electrical feed lines from the contact of the solar cells to the socket for the external terminals, for example, by introducing the metal conductors into the cavity before the injection procedure or by a 3-D MID process (MID=molded interconnected devices). The technologies suitable for the integration of the electrical terminal structure, such as conductor tracks in injection-molded plastic parts, are known in plastic processing.

The socket can also be molded in the process of shaping the plastic carrier, for example, from the same plastic as the carrier, or from another plastic using multicomponent injection molding. The mold and injection-molding technologies required for the shaping of the socket and the seal of the cable from the solar cells to the socket are known in plastic processing.

Further layers may be applied on the side of the rear side construction facing toward the front side, such as an IR-reflecting plastic layer for better usage of the incident light to increase the efficiency or as barrier layers. The layers may be applied to the carrier either after the shaping or in the process of the shaping in the mold using known technologies in plastic processing which are for example, in-mold coating or a spray application or flooding using a reactive polymer in the mold or by laying and in-mold labeling of films in the mold before the injection of the plastic for the carrier.

In a preferred embodiment, the rear side construction also contains fastening elements for the later installation, which are introduced as inlay parts (inserts) into the mold cavity and may be integrated non-positively in the carrier during the shaping in this way. The fastening elements are positioned at the corresponding points in the mold in a way typical for those skilled in the art before the extrusion coating. The technologies required for inserts are known in plastic processing. The inserts may also, upon appropriate implementation and embedding in the rear side construction, unfold an additional support effect and effects which improve the strength of the rear side construction.

After the production of the rear side construction, the solar cells are laid on the carrier and their terminals are connected to the contact points of the electrical terminal structure which are integrated into the carrier such as electrical feed lines to the sockets. The solar cells may not be interconnected or may already be partially interconnected before the application on the carrier, for example, in the case of wafer-based cells in the form of strings, or may be completely interconnected, for example, as interconnected thin-film module or, in the case of wafer-based cells, as a prefinished film having the contacted solar cells attached thereon, which contain the conductor tracks for the interconnection of the individual cells among one another.

In an advantageous embodiment, at the points at which the cells are placed, the rear side construction contains a boundary or support structures, which are implemented as web-shaped or ribbed, for each cell, which allow fixing of the cells. This can either be a depression in which the cells are inlaid, or a small protrusion on the edges of each cell. In addition, the surface of the rear side construction is structured at the points at which the cells rest on the rear side construction so that the cells do not press flatly against it, in order to ensure the adhesive flows completely around the cells when it is introduced later into the intermediate space between pane and rear side construction for gluing thereof.

The connection of the electrical terminals of the solar cell configuration to the contacts on the rear side construction and the feed lines to the socket for the external terminals is performed by known connection techniques, such as soldering, wire bonding, or other typical technologies.

Alternatively, the electrical connection of the electrical terminals of the solar cells to the contacts on the rear side construction can be produced by conductive adhesives. In this case, the adhesive, which is first applied to the contacts on the plastic carrier and cures after the contacting with the electrical terminals of the photoactive elements, forms the solder. Using conductive adhesives, wafer-based solar cells which are not interconnected and are contacted on the rear side may be contacted directly with the contacts on the rear side construction without further wiring, so that the individual solar cells are situated closely adjacent to one another due to the absence of further wiring and the yield per unit of area can thus be increased.

Instead of the preferred use of thermoplastics or duroplastics as the base material for the structure of the rear side construction, organic or ceramic materials are also suitable as the base material for the rear side construction, in which electrical terminal structures are integrated for the electrical connection of the solar cell configuration among one another and also for the electrical connection of the solar module to an external consumer circuit for current collection. At least one section of the electrical terminal structure is also completely enclosed by the organic or ceramic material in this case and at least one other section of the terminal structure has a free contact area facing toward the solar cell configuration and a free contact area or an electrical line for connecting the module to the outside for current collection.

In addition to the electrical terminal structure, a support structure, which comprises glass, ceramic, or a plastic, preferably reinforced with fibers, is at least partially integrated within the rear side construction manufactured from organic or ceramic material. A support structure manufactured from metal would also be conceivable, which also functions as a section of the electrical terminal structure for the electrical connection of the solar cell configuration among one another and the solar cell configuration to the electrical terminals of the module to the outside for current collection.

Depending on the material selection and implementation of the support structure, implementing at least sections of the support structure as individual or coherent profiles, in the form of strands, strips, or latticed braids, is provided, which, touching one another or not touching one another, are provided in the material matrix of the rear side construction.

The front pane is located on the front side of the solar module. The thickness of the front pane is in the range between a few tenths of a millimeter and a few millimeters. The front pane preferably comprises a transparent plastic, for example, based on PMMA.

In the case of thin-film cells, which are typically already deposited on a pane made of glass, plastic, glass-ceramic, or ceramic, for example, this pane is the front pane of the module.

In an advantageous embodiment, known anti-reflective layers or textures may be applied on the surface of the pane facing toward the incident light to reduce the reflected component of the incident light.

In an advantageous embodiment, the front pane can also be provided with fillers to increase the photon yield, which convert the wavelength of the incident light and in this way increase the quantum yield in the wavelength range in which the photoactive cells have their greatest efficiency.

The intermediate space between pane and rear side construction is filled without bubbles using a polymer which glues the front pane to the rear side construction, on the one hand, and protects the photoactive cells located in the intermediate space between rear side construction and front pane and the contact and conductor track system from media influence, on the other hand. In the case of wafer-based cells, preferably a highly transparent, elastic polymer is used. The thickness of the intermediate space is in the range of a few tenths of a millimeter to a few millimeters.

The thermal strains caused by changing temperatures and various coefficients of expansion of the materials are of special significance for the long-term stability of the solar modules according to the invention. These strains may result in defects in the solar cells or on the contact and conductor track system, delamination between rear side construction and adhesive layer or adhesive layer and front pane, and destruction of the module composite. Temperature-related mechanical strains in the area between front pane and rear side construction are extensively reduced by the use of an elastic polymer of the adhesive layer.

Ultrathin gaps of a few micrometers may be filled without pores by the use of a plastic encapsulation which can be processed at low viscosities, for example, at room temperature in the range of a few thousands of millipascals or less, for example, as a reactive system or as a dispersion.

The polymer of the plastic encapsulation can either first be applied on the rear side construction having the electrically contacted solar cells and then the front pane can be laid thereon. For example, an unpressurized casting method is suitable for the application of the polymer of the plastic encapsulation on the rear side construction. The corresponding technologies are known to those skilled in the art.

However, the front pane can also first be fixed in its final position over the rear side construction using fixing aids, such as a tool, and the polymer of the plastic encapsulation can then be introduced into the intermediate space between front pane and rear side construction. Both high-pressure and also low-pressure methods may be used for this purpose. The corresponding technologies are known to those skilled in the art.

Transparent polyurethane systems are suitable as polymers of the plastic encapsulation, for example, made of aliphatic polyisocyanates, native polyurea systems, casting silicones, native epoxides, and plastisols.

### BRIEF DESCRIPTION OF THE DRAWINGS

The invention is explained hereafter for exemplary purposes without restriction of the general concept of the invention on the basis of exemplary embodiments with reference to the drawings. In the figures:

FIGS. 1a-e show a sequential image illustration of the manufacturing of the solar module

### DESCRIPTION OF THE INVENTION

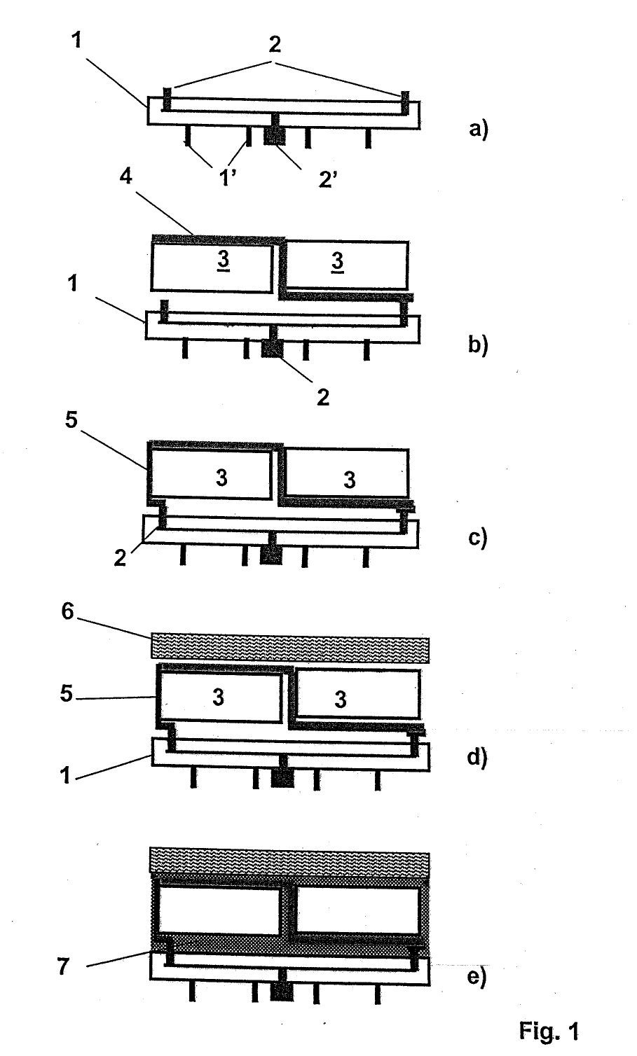

Manufacturing steps for the cost-effective production of a solar module are shown in FIGS. 1a through e.

A plastic carrier 1 is shown as a rear side construction in FIG. 1a, which is produced from a plastic material in the course of an injection molding or injection-compression molding method or in the course of a compression method. In addition, an electrical terminal structure 2 for the later electrical contacting of the solar cell configuration is provided within the plastic carrier 1. The electrical terminal structure 2 is advantageously implemented as stiff at least in the sections in which it is completely enveloped by the plastic material of the plastic carrier 1, for example, by profiling as rails. The plastic carrier experiences improved surface stiffness through the embedded electrical terminal structure 2. In addition, the plastic carrier 1 has ribbed struts 1′ on its rear side, which are used, on the one hand, for further stabilization and also for fastening of the solar module. The struts 1′ are not necessarily manufactured from the same material which the plastic carrier 1 comprises. Glass, ceramic, metal, fiber-reinforced composite materials, or similar stiff materials are incorporated at least partially in the plastic carrier.

The electrical terminal structure 2 has a central socket 2′ on the rear side of the plastic carrier 1, via which the finished solar module can be connected to an external control and supply unit. The socket 2 is also at least partially integrally incorporated in the plastic carrier 1.

In the manufacturing step according to FIG. 1b, a series (“string”) 4 of interconnected solar cells 3 is brought into position on the front side of the plastic carrier 1 and connected in the method step according to FIG. 1c using electrical connections 5 to the electrical terminal structure 2 integrated in the plastic carrier 1. Receptacle structures formed on the front side of the plastic carrier 1, which are manufactured from plastic, are not shown in detail, in which the solar cells 3 connected via the frame 4 may be fitted, so that the solar cells 3 may be brought into contact in a predefined location relative to the plastic carrier 1.

In the manufacturing step according to FIG. 1d, a radiation-transparent front pane 6, preferably comprising PMMA material, is applied to the solar cell configuration 3, 4, so that an intermediate space is formed between the front pane 6 and the plastic carrier 1, which is completely filled in the manufacturing step shown in FIG. 1f using a grouting compound 7. The grouting compound 7 is used like an adhesive layer, by which the front pane 6 is intimately connected to the plastic carrier 7, so that the grouting compound 7 is capable of transmitting mechanical loads accordingly. The grouting compound 7 also completely hermetically encloses the internal solar cell configuration 3+4, that is, the side flanks of the solar cell configuration are also enclosed by the grouting compound 7.

The solar module implemented according to the invention thus has the following advantages:

Through the construction of the solar module from a separate carrier and a separate front pane, which are flatly glued to one another by an embedding material, both contribute to the bending stiffness. In addition, there is the contribution to the bending stiffness by the electrical terminal structure and optionally the additional support structure, which are each implemented as at least partially integral components of the rear side construction.

Injection-moldable thermoplastics or duroplastics may be used for the plastic carrier and it may be implemented having a high bending stiffness and bending strength.

The front pane is produced from a radiation-transparent material, preferably from plastic based on PMMA, which is proven to have high long-term UV stability, a low density, and a high bending stiffness.

The front pane and the plastic carrier having the solar cell configuration lying in between are glued to one another in the course of a low-tension casting process, so that high long-term durability thereof is guaranteed under alternating usage conditions with respect to temperature variations and mechanical strains.

The manufacturing time of the production of the solar module according to the invention can be significantly shortened by corresponding decoupling of the manufacturing of front and plastic carrier sides.

### LIST OF REFERENCE NUMERALS

1 plastic carrier
1′ ribbed struts
2 electrical terminal structure
2′ socket
3 solar cells
4 frame elements
5 electrical connection structure
6 front pane
7 grouting compound

1-22. (canceled)

23. A solar module comprising:
a flat solar cell configuration, including a rear side and a front side with a radiation-transparent front pane including a solidifying grouting compound, which encloses the solar cell configuration between rear side and the front pane, transmits mechanical loads, and connects the surface of the front pane facing toward the rear side over an entire area of the front pane to the rear side to enclose the solar cell configuration; and wherein
the rear side is a separate module comprising a plastic carrier which provides an electrical terminal, integrated in the plastic carrier for providing an electrical connection to the solar cell configuration so that at least one part of the electrical terminal is enclosed by the plastic carrier and at least one other part of the electrical terminal has a free contact area facing toward the solar cell configuration.

24. A solar module comprising:
a flat solar cell configuration, including a rear side and a front side with a radiation-transparent front pane including solidifying grouting compound, which encloses the solar cell configuration between rear side and front pane, transmits mechanical loads and connects the surface of the front pane facing toward the rear side over an entire area of the front panel to the rear side to enclose the solar cell configuration; and wherein
the rear side is a separate module comprising a ceramic or organic planar element which includes an electrical terminal for providing an electrical connection to the solar cell configuration which is integrated in the rear side so that at least one part of the electrical terminal is enclosed by the ceramic or organic planar element and at least one other part of the electrical terminal has a free contact area facing toward the solar cell configuration.

25. The solar module according to claim 23, wherein the front pane comprises glass, glass-ceramic, or a transparent PMMA-based plastic.

26. The solar module according to claim 24, wherein the front pane comprises glass, glass-ceramic, or a transparent PMMA-based plastic.

27. The solar module according to claim 23, wherein the solar cell configuration is located between the front pane and the rear side in an area of a neutral bending plane caused by sagging of the solar module.

28. The solar module according to claim 24, wherein the solar cell configuration is located between the front pane and the rear side in an area of a neutral bending plane caused by sagging of the solar module.

29. The solar module according to claim 25, wherein the solar cell configuration is located between the front pane and the rear side in an area of a neutral bending plane caused by sagging of the solar module.

30. The solar module according to claim 26, wherein the solar cell configuration is located between the front pane and the rear side in an area of a neutral bending plane caused by sagging of the solar module.

31. The solar module according to claim 23, wherein the plastic carrier comprises PBT, PET, PA, PMMA, PC, PT or biopolymers.

32. The solar module according to claim 23, wherein the plastic carrier comprises a fiber-reinforced plastic.

33. The solar module according to claim 23, wherein the plastic carrier comprises one or more of metal powder, chalk, glass lamina and silicates.

34. The solar module according to claim 23, wherein an electrical connection is provided between the solar cell configuration and the electrical terminal by direct electrical contact using electrically conductive adhesives, wire bonding, and/or using soldered or welded bonds.

35. The solar module according to claim 24, wherein an electrical connection is provided between the solar cell configuration and the electrical terminal by direct electrical contact using electrically conductive adhesives, wire bonding, and/or using soldered or welded bonds.

36. The solar module according to claim 23, wherein the plastic carrier comprises a fiber-reinforced plastic.

37. The solar module according to claim 23, wherein the rear side comprises a receptacle and/or fixing structure for the solar cell configuration on a side facing toward the solar cell configuration.

38. The solar module according to claim 24, wherein the rear side comprises a receptacle and/or fixing structure for the solar cell configuration on a side facing toward the solar cell configuration.

39. The solar module according to claim 23, wherein the front pane has a thickness between tenths of a millimeter and millimeters.

40. The solar module according to claim 24, wherein the front pane has a thickness between tenths of a millimeter and millimeters.

41. The solar module according to claim 23, wherein an anti-reflective layer is applied on the surface of the front pane facing away from the solar module.

42. The solar module according to claim 24, wherein an anti-reflective layer is applied on the surface of the front pane facing away from the solar module.

43. The solar module according to claim 23, wherein the front pane comprises materials for converting a wavelength of the radiation incident on the front pane so that the radiation converted in the wavelength achieves a higher efficiency in the solar cell configuration than non-converted radiation.

44. The solar module according to claim 24, wherein the front pane comprises materials for converting a wavelength of the radiation incident on the front pane so that the radiation converted in the wavelength achieves a higher efficiency in the solar cell configuration than non-converted radiation.

45. The solar module according to claim 23, wherein the solar cell configuration is a thin-film solar cell having a radiation-transparent cover layer, and the cover layer is the front pane which is enclosed at least in the surface area proximate to an edge of the radiation-transparent grouting compound and produces a load-transferring connection to the rear side construction.

46. The solar module according to claim 24, wherein the solar cell configuration is a thin-film solar cell having a radiation-transparent cover layer, and the cover layer is the front pane which is enclosed at least in the surface area proximate to an edge of the radiation-transparent grouting compound and produces a load-transferring connection to the rear side construction.

47. The solar module according to claim 23, wherein the electrical terminal provides protruding support elements facing toward the solar cell configuration providing local electrical and/or supporting contact.

48. The solar module according to claim 24, wherein the electrical terminal provides protruding support elements facing toward the solar cell configuration providing local electrical and/or supporting contact.

49. The solar module according to claim 47, wherein the support elements have a height causing solar cell configuration to rest in an area of the neutral chamfer of the solar module.

50. The solar module according to claim 48, wherein the support elements have a height causing solar cell configuration to rest in an area of the neutral chamfer of the solar module.

51. The solar module according to claim 23, wherein the electrical terminal includes sections which are an integral component within the rear side for increasing the mechanical stability of the rear side construction.

52. The solar module according to claim 24, wherein the electrical terminal includes sections which are an integral component within the rear side for increasing the mechanical stability of the rear side construction.

53. The solar module according to claim 23, wherein the rear includes a support structure comprising a material, different from the material of the rear side, and at least one section of the support structure is completely enclosed by the rear side construction.

54. The solar module according to claim 24, wherein the rear includes a support structure comprising a material, different from the material of the rear side, and at least one section of the support structure is completely enclosed by the rear side construction.

55. The solar module according to claim 53, wherein the support structure comprises one or more of: metal, glass, ceramic, plastic and fiber-reinforced composite material.

56. The solar module according to claim 54, wherein the support structure comprises one or more of: metal, glass, ceramic, plastic and fiber-reinforced composite material.

57. The solar module according to claim 53, wherein at least sections of the support structure are implemented as bars, strips, or lattices.

58. The solar module according to claim 54, wherein at least sections of the support structure are implemented as bars, strips, or lattices.

59. The solar module according to claim 53, wherein at least one section of a metal support structure is a section of the electrical terminal for the electrical connection of the solar cell configuration to the electrical terminals to supply current from the solar cell configuration.

60. The solar module according to claim 55, wherein at least one section of a metal support structure is a section of the electrical terminal for the electrical connection of the solar cell configuration and the solar cell configuration to the electrical terminals to supply current from the solar cell configuration current.

61. The solar module according to claim 23, comprising an IR-reflecting layer applied on a surface of the plastic carrier facing toward the solar cell configuration.

62. The solar module according to claim 23, wherein the grouting compound is a radiation-transparent elastic polymer, selected from the group consisting of transparent polyurethanes, aliphatic polyisocyanates, native polyurea systems, casting silicones, native epoxides and plastisols.

63. The solar module according to claim 24, wherein the grouting compound is a radiation-transparent elastic polymer, selected from the group consisting of transparent polyurethanes, aliphatic polyisocyanates, native polyurea systems, casting silicones, native epoxides and plastisols.

64. The solar module according to claim 23, wherein the rear side module is injection molded, injection compression molded or compression molded.
